(19) United States
(12) Patent Application Publication
(10) Pub. No.: US 2026/0342308 A1
(43) Pub. Date: Oct. 29, 2026

(54) ACOUSTIC WAVE DEVICE HAVING ACOUSTIC WAVE PHASE DISPERSION STRUCTURE

(71) Applicant: PENTASTONE ELECTRONICS, INC., Seongnam-si (KR)

(72) Inventors: Dae Kyu YU, Seoul (KR); Kyoung Joon MIN, Seongnam-si (KR); Kyung Oh KIM, Seoul (KR); Jung-Geun Shin, Ansan-si (KR)

(73) Assignee: PENTASTONE ELECTRONICS, INC., Seongnam-si (KR)

(21) Appl. No.: 19/656,973

(22) Filed: Apr. 23, 2026

(30) Foreign Application Priority Data
Apr. 25, 2025 (KR) 10-2025-0054235

(51) Int. Cl. H03H 9/02; H03H 9/145; H03H 9/25

(52) U.S. Cl. CPC H03H 9/02818; H03H 9/02637; H03H 9/145; H03H 9/25

(57) ABSTRACT

The acoustic wave device having an acoustic wave phase dispersion structure according to the present invention converts an electrical signal into an acoustic wave of a piezoelectric material using a piezoelectric effect of the piezoelectric material and converts the converted acoustic wave back into an electrical signal, and has an effect of effectively reducing a spurious response on a frequency response and reducing a ripple in a passband by dispersing a phase of the acoustic wave reflected to an IDT electrode.

### CROSS-REFERENCE TO RELATED APPLICATION

This application is based on and claims priority under 35 U.S.C. § 119 to Korean Patent Application Nos. 10-2025-0054235 filed on Apr. 25, 2025, in the Korean Intellectual Property Office, the disclosure of which is incorporated by reference herein in its entirety.

### BACKGROUND OF THE INVENTION

### Field of the Invention

The present invention relates to an acoustic wave device converting an electrical signal into an acoustic wave of a piezoelectric material using a piezoelectric effect of the piezoelectric material and converting the converted acoustic wave back into an electrical signal, and more particularly, to an acoustic wave device having an acoustic wave phase dispersion structure configured to disperse a phase of the acoustic wave to reduce a spurious response on a frequency response.

Information on National R&D Project supporting the present invention is as follows.
[Project Number] 20240011
[Assignment Number] RS-2024-00397896
[Name of Department] Ministry of Science and ICT
[Research and Management Institution] Institute of Information & Communications Technology Planning & Evaluation
[Research Program Name] Development of Broadcasting and Communications Industry Technology
[Research Project Title] Development of high-efficiency RF module that supports 5G smartphone-oriented n77~n79 band MIMO
[Project Implementation Agency] PENTASTONE ELECTRONICS, INC [Research Period] 2025.01.01~2025.12.31

### Description of the Related Art

With the development of mobile communication devices such as smartphones and tablets, there is a demand for high performance of acoustic wave elements and devices such as surface acoustic wave (SAW) resonators and filters using the same. At the same time, due to the need to mount more acoustic wave devices in a limited space such as a mobile phone according to the miniaturization and integration of devices, additional configurations for improving the performance of the acoustic wave device are inevitably avoided, and a method capable of improving the performance of the acoustic wave device within an existing configuration must be studied.

FIG. 1 shows a structure of a conventional typical surface acoustic wave (SAW) resonator. Such a conventional SAW resonator includes an interdigital transducer (IDT) structure 10 formed by continuously arranging metal electrodes in parallel on a piezoelectric substrate (PS) made of a piezoelectric material. When an AC signal voltage is applied to the IDT 10, an electric field is generated between electrodes 11 and 12 inside the IDT, and deformation occurs on the surface of the substrate due to the piezoelectric effect of the piezoelectric substrate, so that a surface acoustic wave (SAW) propagates in both directions of the IDT.

In this way, the surface acoustic wave generated on the piezoelectric substrate by the IDT 10 can perform a function of a bandpass filter that passes a frequency component synchronized with the frequency of the surface acoustic wave and attenuates the remaining signals in the process of converting the surface acoustic wave back into an electrical signal by an output electrode in the IDT or another IDT disposed adjacent thereto.

At this point, reflectors 20 and 30 forming gratings 22 of metal thin films are provided around the IDT 10 on the piezoelectric substrate to reflect the surface acoustic wave generated by the IDT 10, thereby reducing loss.

That is, the reflectors 20 and 30 of the typical SAW resonator as shown in FIG. 1 serve to confine the surface acoustic wave inside the SAW resonator by reflecting the surface acoustic wave generated from the IDT 10 at both ends of the IDT 10 in accordance with a Bragg condition.

As shown in FIG. 1, a plurality of electrodes 11 and 12 provided in the IDT 10 and electrodes 22 of the reflectors 20 and 30 of the typical SAW resonator all have a constant period of po.

In this way, when the periods of the electrodes of the IDT and the electrodes of the reflector are set to the same period, the reflector confines the surface acoustic wave generated from the IDT in the resonator according to the Bragg condition, thereby concentrating surface acoustic wave energy at a resonance frequency, which has an advantage of increasing a Q-Factor.

However, most of the surface acoustic waves generated from the IDT experience multiple reflections while passing through an IDT boundary, which becomes a factor causing a strong spurious response (Spurious Response) to appear before a resonance frequency and after an anti-resonance frequency on a frequency response.

Such a spurious response negatively affects filter performance, and in particular, causes a problem of inducing a ripple in a passband of the frequency response of the filter and adversely affecting out-of-band rejection.

In particular, in a structure that effectively concentrates the surface acoustic wave generated from the IDT on the surface of the piezoelectric substrate, such as a thin film SAW (TF-SAW), the spurious response also increases, so that the ripple problem in the passband caused by the spurious response becomes more serious.

As related prior art documents, JP7008633, JP4843862, US2023-0008248, JP2011-023894, etc. are disclosed.

### SUMMARY OF THE INVENTION

An object of the present invention is to provide an acoustic wave device having an acoustic wave phase dispersion structure, which converts an electrical signal into an acoustic wave of a piezoelectric material using a piezoelectric effect of the piezoelectric material and converts the converted acoustic wave back into an electrical signal, wherein the acoustic wave device is capable of effectively reducing a spurious response on a frequency response and reducing a ripple in a passband by dispersing a phase of the acoustic wave reflected to an IDT electrode.

An acoustic wave device having an acoustic wave phase dispersion structure according to an embodiment of the present invention comprises: a piezoelectric substrate; an IDT electrode disposed on the piezoelectric substrate and including a plurality of electrode fingers configured to convert an electrical signal into an acoustic wave on the piezoelectric substrate; and a phase dispersion reflector respectively disposed in a propagation direction of the acoustic wave generated by the IDT electrode and including a plurality of reflection electrodes configured to reflect the acoustic wave to the IDT electrode, wherein a period of the plurality of reflection electrodes is set such that a phase of the reflected acoustic wave is dispersed.

Preferably, the phase dispersion reflector is configured such that a portion of the plurality of reflection electrodes disposed adjacent to the IDT electrode is set to have at least one period shorter than a period of the IDT electrode, and the remainder of the plurality of reflection electrodes is set to have at least one period longer than the period of the IDT electrode.

Preferably, the phase dispersion reflector comprises: a first reflection part including a plurality of reflection electrodes having a period set to induce phase dispersion of the acoustic wave generated from the IDT electrode; and a second reflection part including a plurality of reflection electrodes having a period set to change a phase of the acoustic wave passing through the first reflection part to satisfy an acoustic wave reflection condition to the IDT electrode.

Preferably, the phase dispersion reflector comprises: a first reflection part including a plurality of reflection electrodes set to have at least one period shorter than a period of the IDT electrode; and a second reflection part including a plurality of reflection electrodes set to have at least one period longer than the period of the IDT electrode.

Preferably, the phase dispersion reflector comprises: a first reflection part configured to have a period shorter than a period of the IDT electrode, wherein the period of the plurality of reflection electrodes is set to gradually increase in a direction away from the IDT electrode from a position adjacent to the IDT electrode; and a second reflection part configured to have a period longer than the period of the IDT electrode, wherein the period of the plurality of reflection electrodes is set to gradually increase or gradually decrease in a direction away from the IDT electrode from a position connected to the first reflection part.

Preferably, the phase dispersion reflector is configured by setting the number of reflection electrodes included in the second reflection part to be at least four times greater than the number of reflection electrodes included in the first reflection part.

Preferably, the phase dispersion reflector is configured such that: each of one or more periods set for the plurality of reflection electrodes included in the first reflection part is shorter than a period of the IDT electrode, and a difference value from the period of the IDT electrode is set to be 5% or less of the period of the IDT electrode; and each of one or more periods set for the plurality of reflection electrodes included in the second reflection part is longer than the period of the IDT electrode, and a difference value from the period of the IDT electrode is set to be 5% or less of the period of the IDT electrode.

Preferably, a period of the phase dispersion reflector is set such that an average value of periods set for all reflection electrodes of the phase dispersion reflector is equal to a period of the IDT electrode or included in a preset difference value range.

### BRIEF DESCRIPTION OF THE DRAWINGS

FIG. 1 shows a structure of a conventional typical surface acoustic wave (SAW) resonator.

FIG. 2 shows a basic configuration of an acoustic wave device according to an embodiment of the present invention and details regarding a change in period of the acoustic wave device.

FIG. 3 shows a basic configuration of an acoustic wave device according to another embodiment of the present invention and details regarding a change in period of an IDT electrode and a phase dispersion reflector accordingly.

FIG. 4 shows a configuration of an acoustic wave device according to still another embodiment of the present invention and details regarding a change in period of an IDT electrode and a phase dispersion reflector accordingly.

FIG. 5 is a graph showing a comparison of frequency responses between a SAW resonator to which the phase dispersion reflector as shown in FIG. 2 is applied as an acoustic wave device according to an embodiment of the present invention, and a typical SAW resonator.

FIG. 6 is a graph comparing the frequency responses of a filter composed of typical SAW resonators and a filter composed of an acoustic wave device according to the present invention, showing improved spurious rejection in the out-of-band region.

FIG. 7 is a graph comparing the frequency responses of a filter composed of typical SAW resonators and a filter composed of an acoustic wave device according to the present invention, showing reduced ripple within the passband.

FIG. 8 is a graph comparing the frequency responses of a filter composed of typical SAW resonators and a filter composed of an acoustic wave device according to the present invention, showing a reduction in passband ripple and improved spurious rejection in the out-of-band region.

### DESCRIPTION OF THE PREFERRED EMBODIMENTS

Specific details regarding the acoustic wave device having an acoustic wave phase dispersion structure according to the present invention will be described in detail with reference to the accompanying drawings.

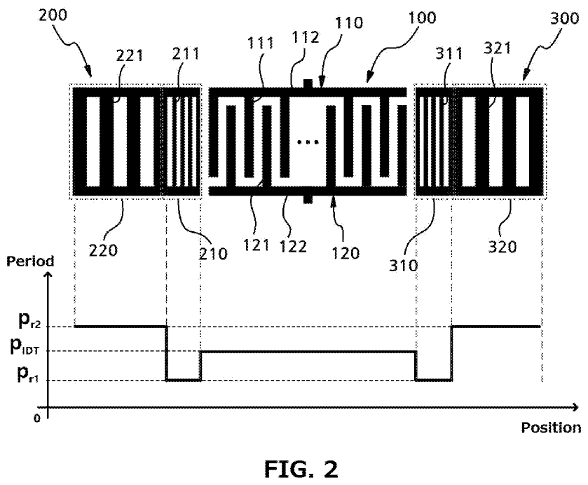

First, a configuration of an acoustic wave device having an acoustic wave phase dispersion structure according to an embodiment of the present invention will be described with reference to FIG. 2. FIG. 2 shows a basic configuration of an acoustic wave device according to an embodiment of the present invention and details regarding a change in period of the acoustic wave device.

As shown in FIG. 2, the acoustic wave device according to an embodiment of the present invention includes an IDT electrode 100 and phase dispersion reflectors 200 and 300 respectively provided at both ends thereof, all of which are provided on a piezoelectric substrate. In the drawings, the illustration of the piezoelectric substrate is omitted for convenience, and the same applies hereinafter.

The IDT electrode 100 is provided on the piezoelectric substrate and converts an electrical signal into an acoustic wave on the piezoelectric substrate, or conversely, converts an acoustic wave on the piezoelectric substrate into an electrical signal, or performs both.

The IDT electrode 100 is configured to include a plurality of electrode fingers (111, 121, etc.) that convert an electrical signal into an acoustic wave on the piezoelectric substrate.

Specifically, as shown in FIG. 2, the IDT electrode 100 has a configuration in which a plurality of metal electrodes having a comb structure, that is, a plurality of electrode fingers, are divided into an input IDT electrode unit 110 and an output IDT electrode unit 120 so that a plurality of input electrode fingers (111, etc.) and a plurality of output electrode fingers (121, etc.) are alternately arranged. The IDT electrode 100 includes an input electrode busbar 112 connecting the plurality of input electrode fingers (111, etc.) and an output electrode busbar 122 connecting the plurality of output electrode fingers (121, etc.).

When an electrical signal is applied through the input IDT electrode unit 110, an acoustic wave is generated on the piezoelectric substrate by an electric field between the plurality of input electrode fingers (111, etc.) and the output electrode fingers (121, etc.), and the acoustic wave is converted back into an electrical signal and output to the output IDT electrode unit 120.

In this instance, the acoustic wave generated from the IDT electrode 100 propagates in both directions, that is, in the left and right directions in the drawing, respectively.

By providing the phase dispersion reflectors 200 and 300 forming gratings of metal thin films at both end portions of the IDT electrode 100 in the propagation direction of the acoustic wave generated from the IDT electrode 100 on the piezoelectric substrate, the acoustic wave generated by the IDT electrode 100 and propagating to the outside is reflected back to the IDT electrode 100, thereby reducing a loss caused by the propagation of the acoustic wave.

That is, the phase dispersion reflectors 200 and 300 serve to confine the acoustic wave inside the acoustic wave device by reflecting the acoustic wave generated from the IDT electrode 100 at both ends of the IDT electrode 100.

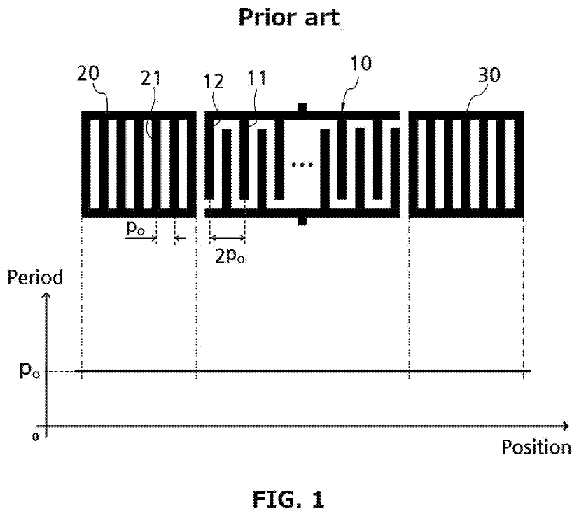

If the reflector is configured to have a plurality of reflection electrodes with a constant period in accordance with a Bragg condition (the configuration of the reflector of the conventional acoustic wave device shown in FIG. 1), multiple reflections occur within the reflector, which causes a spurious response to appear strongly at a position before a resonance frequency and a position after an anti-resonance frequency on a frequency response.

In order to solve this problem, the present invention uses a phase dispersion reflector having sections with a plurality of different periods instead of a conventional reflector to disperse the phase of the reflected acoustic wave, thereby reducing constructive interference and lowering a peak size in the spurious response of the reflected acoustic wave.

That is, the present invention relates to a destructive interference mechanism that induces unwanted parasitic resonances (spurious responses) to cancel each other out, rather than creating a new resonance point, by implementing the phase dispersion reflector to have a different period from the IDT electrode to finely disperse the phase of the reflected wave.

The phase dispersion reflector provided in the acoustic wave device according to an embodiment of the present invention may be configured such that a portion of the plurality of reflection electrodes disposed adjacent to the IDT electrode is set to have at least one period shorter than the period of the IDT electrode, and the remainder of the plurality of reflection electrodes is set to have at least one period longer than the period of the IDT electrode.

For example, as shown in FIG. 2, the phase dispersion reflectors 200 and 300 respectively provided at both ends of the IDT electrode 100 include first reflection parts 210 and 310 and second reflection parts 220 and 320, respectively, and each of the first reflection part and the second reflection part includes a plurality of reflection electrodes set to have different periods.

Since the phase dispersion reflectors are respectively provided at both ends of the IDT electrode 100 with the same configuration, the phase dispersion reflector provided on one side of the IDT electrode will be described in detail below, and a description of the phase dispersion reflector provided on the other side of the IDT electrode will be omitted because it has the same configuration as the phase dispersion reflector on the one side.

In the phase dispersion reflector 200, the first reflection part 210 is disposed at a position close to the IDT electrode 100, and the second reflection part 220 is disposed connected thereto, so that the first reflection part 210 and the second reflection part 220 constitute a single reflector.

In the phase dispersion reflector 200, the first reflection part 210 may be configured to include a plurality of reflection electrodes 211 set to at least one period (pᵣ₁) shorter than the period (p_{IDT}) of the IDT electrode to induce phase dispersion of the acoustic wave generated and propagating from the IDT electrode 100. The second reflection part 220 may be configured to include a plurality of reflection electrodes 221 set to at least one period (pᵣ₂) longer than the period (p_{IDT}) of the IDT electrode 100 to change a phase of the acoustic wave passing through the first reflection part 210 to satisfy an acoustic wave reflection condition to the IDT electrode 100. The first reflection part 310 and the second reflection part 320 of the phase dispersion reflector 300 on the opposite side also have the same configuration.

Since the amount of reflected acoustic wave energy is larger as it is closer to the IDT electrode, it is preferable to set the number of reflection electrodes constituting the first reflection part 210 adjacent to the IDT electrode 100 to be small and to set the number of reflection electrodes constituting the second reflection part 220 far from the IDT electrode 100 to be large.

That is, as the acoustic wave generated and propagating from the IDT electrode 100 passes through the first reflection part 210 having the pᵣ₁ period with a fast phase change, the phase of the acoustic wave having a large amount of energy is dispersed. Then, as it passes through the second reflection part 220 having the pᵣ₂ period with a slow phase change, the phase of the acoustic wave having a smaller amount of energy changes to meet the reflection condition (to minimize a change to the resonance frequency). Therefore, it is necessary to appropriately adjust the number of reflection electrodes in each of the first reflection part 210 and the second reflection part 220 in order to balance the acoustic wave energy passing through the first reflection part 210 and the acoustic wave energy passing through the second reflection part 220.

For example, the number N₁ of the reflection electrodes 211 of the first reflection part 210 is configured to be 2 or more and 10 or less (N₁=2 to 10), and the number N₂ of the reflection electrodes 221 of the second reflection part 220 is configured to be 4 times or more the number of reflection electrodes of the first reflection part 210 (N₂≥4*N₁), thereby dispersing the phase of the reflected acoustic wave so that the spurious response is reduced while minimizing the change in the resonance frequency.

As shown in FIG. 2, the electrode period of the plurality of electrode fingers 111 and 121 constituting the IDT electrode 100 is referred to as p_{IDT}, the period of the reflection electrodes 211 of the first reflection part 210 of the phase dispersion reflector 200 is referred to as pᵣ₁, and the period of the reflection electrodes 221 of the second reflection part 220 of the phase dispersion reflector 200 is referred to as pᵣ₂. As shown in FIG. 2, pᵣ₁, which is the period of the first reflection part 210, may be set shorter than the period p_{IDT} of the IDT electrode 100, and pᵣ₂, which is the period of the second reflection part 220, may be set longer than the period p_{IDT} of the IDT electrode 100. That is, looking at the graph of the period of the electrode versus position shown in FIG. 2, pᵣ₁<p_{IDT}<pᵣ₂.

As described above, by setting the period pᵣ₁ of the first reflection parts 210 and 310 of the phase dispersion reflectors 200 and 300 to be shorter than p_{IDT} and setting the period pᵣ₂ of the second reflection parts 220 and 320 to be longer than p_{IDT}, while setting each period value of pᵣ₁ and pᵣ₂ such that the overall phase change of the acoustic wave becomes substantially the same as that of the IDT electrode 100, it is possible to cancel the spurious response while minimizing the change in the resonance frequency of the acoustic wave device.

To this end, the period pᵣ₁ of the reflection electrodes of the first reflection parts 210 and 310 of the phase dispersion reflectors 200 and 300 is preferably set as shown in Equation 1 below.

pᵣ₁=p_{IDT}·(1−Δ₁), Δ₁≤5% [Equation 1]

In addition, the period pᵣ₂ of the reflection electrodes of the second reflection parts 220 and 320 of the phase dispersion reflectors 200 and 300 is preferably set as shown in Equation 2 below.

pᵣ₂=p_{IDT}·(1+Δ₂), Δ₂≤5% [Equation 2]

That is, it is preferable that the period pᵣ₁ of the reflection electrodes of the first reflection parts 210 and 310 is a period shorter than the period p_{IDT} of the IDT electrode 100, and is set such that a difference value from the period p_{IDT} of the IDT electrode 100 is 5% or less of the period p_{IDT}. Further, it is preferable that the period pᵣ₂ of the reflection electrodes of the second reflection parts 220 and 320 is a period longer than the period p_{IDT} of the IDT electrode 100, and is set such that a difference value from the period p_{IDT} of the IDT electrode 100 is 5% or less of the period p_{IDT}.

By setting each period value of pᵣ₁ and pᵣ₂ as in Equations 1 and 2 such that the overall phase change of the acoustic wave is close to the change according to the period of the IDT electrode, the spurious response can be reduced while maximally maintaining the acoustic wave energy concentration effect at the resonance frequency of the acoustic wave device.

Conversely, if the difference value between the period of the reflection electrodes of the phase dispersion reflector and the period of the IDT electrode exceeds 5% of the period of the IDT electrode, a new resonance point may be formed beyond phase dispersion and parasitic resonance may occur. Therefore, the 5% period variation range of the phase dispersion reflector as described above can be considered a critical numerical value.

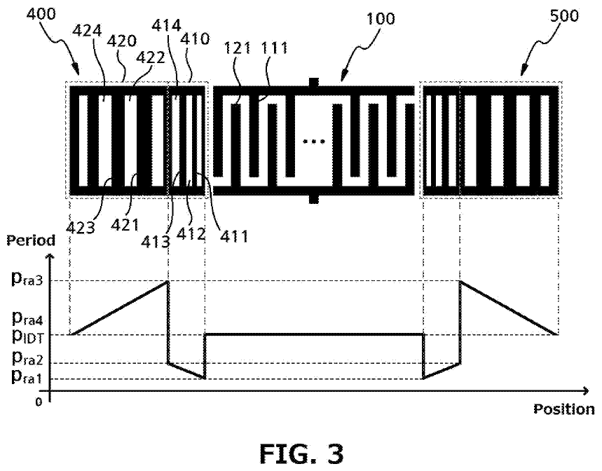

Meanwhile, an acoustic wave device according to another embodiment of the present invention will be described with reference to FIG. 3. FIG. 3 shows a configuration of an acoustic wave device according to another embodiment of the present invention and details regarding a change in period of an IDT electrode and a phase dispersion reflector accordingly.

In the embodiment shown in FIG. 3, the IDT electrode 100 is the same as the embodiment shown in FIG. 2 described above, and there is a difference in the configuration of the phase dispersion reflector. Hereinafter, redundant descriptions of the same configuration will be avoided, and descriptions will focus on portions that differ between the embodiments.

The acoustic wave device according to the embodiment shown in FIG. 2 relates to a configuration in which the first reflection part of the phase dispersion reflector has a constant period pᵣ₁ shorter than the period of the IDT electrode, and the second reflection part has a constant period pᵣ₂ longer than the period of the IDT electrode.

Also in the embodiment shown in FIG. 3, a phase dispersion reflector 400 is divided into a first reflection part 410 and a second reflection part 420, but the period of the first reflection part 410 and the period of the second reflection part 420 are not constant values, but have a configuration in which the period length varies depending on a position. Since a phase dispersion reflector 500 provided at the opposite end of the IDT electrode 100 also has the same configuration, the phase dispersion reflector 400 will be described below, but a description of the opposite phase dispersion reflector 500 will be omitted.

The first reflection part 410 of the phase dispersion reflector 400 provided adjacent to the end portion of the IDT electrode 100 is set to have a period shorter than p_{IDT}, which is the period of the IDT electrode 100, such that the period of the plurality of reflection electrodes (411, 413, etc.) gradually increases in a direction away from the IDT electrode 100 in the propagation direction of the acoustic wave from a position adjacent to the IDT electrode 100. The second reflection part 420 is set to have a period longer than p_{IDT}, which is the period of the IDT electrode 100, such that the period of the plurality of reflection electrodes (421, 423, etc.) gradually decreases in the direction away from the IDT electrode 100 in the propagation direction of the acoustic wave from a position connected to the first reflection part 410.

As the period of the plurality of reflection electrodes (411, 413, etc.) of the first reflection part 410 gradually increases, an interval (412, 414, etc.) between the reflection electrodes also gradually increases. As the period of the plurality of reflection electrodes (421, 423, etc.) of the second reflection part 420 gradually decreases, an interval (422, 424, etc.) between the reflection electrodes also gradually decreases.

As shown in FIGS. 3A and 3B, the electrode period of the plurality of electrode fingers 111 and 121 constituting the IDT electrode 100 is referred to as p_{IDT}. The period of the reflection electrodes (411, 413, etc.) of the first reflection part 410 of the phase dispersion reflector 400 changes such that the period gradually increases from pᵣₐ₁ to pᵣₐ₂ in the acoustic wave propagation direction from a position adjacent to the IDT electrode. The period of the reflection electrodes (421, 423, etc.) of the second reflection part 420 of the phase dispersion reflector 400 changes such that the period gradually decreases from pᵣₐ₃ to pᵣₐ₄ in the acoustic wave propagation direction.

At this point, the period pᵣₐ₁ to pᵣₐ₂ of the first reflection part 410 is set at a period length shorter than p_{IDT} of the IDT electrode 100, and the period pᵣₐ₃ to pᵣₐ₄ of the second reflection part 420 is set at a period length equal to or longer than p_{IDT} of the IDT electrode 100. As shown in FIG. 3, pᵣₐ₁<pᵣₐ₂<p_{IDT}≤pᵣₐ₄<pᵣₐ₃.

At the position of the period pᵣₐ₁ of the first reflection part 410, the period length of the reflection electrode is formed to be the shortest, and gradually increases toward the position pᵣₐ₂. Accordingly, the speed of phase change of the acoustic wave passing through the first reflection part 410 also changes rapidly and then changes slowly little by little, so that the phase of the acoustic wave is dispersed multi-directionally. As it passes through the position of the period pᵣₐ₃ of the second reflection part 420, the phase change of the acoustic wave occurs very slowly, and then changes faster little by little toward the position pᵣₐ₄. As a result, the overall phase change of the acoustic wave is maintained similarly to the phase change of the acoustic wave in the IDT electrode, so that the change in the resonance frequency characteristic can be minimized while suppressing the occurrence of the spurious response.

The period pᵣₐ₁ to pᵣₐ₂ of the first reflection part 410 of the phase dispersion reflector 400 is in a range shorter than the electrode period p_{IDT} of the IDT electrode 100, and the pᵣₐ₁ to pᵣₐ₂ range (pᵣₐ₁<pᵣₐ₂) may be set such that a difference value between any period value within the pᵣₐ₁ to pᵣₐ₂ range and the period p_{IDT} of the IDT electrode 100 is 5% or less of the period p_{IDT}.

For example, it is possible to set and apply the pᵣₐ₁ to pᵣₐ₂ range, which is the period range of the first reflection part, such that the difference value between p_{IDT} and pᵣₐ₁ corresponds to 4% of p_{IDT} and the difference value between p_{IDT} and pᵣₐ₂ corresponds to 3% of p_{IDT}.

The period pᵣₐ₃ to pᵣₐ₄ of the second reflection part 420 of the phase dispersion reflector 400 is in a range longer than the electrode period p_{IDT} of the IDT electrode 100, and the pᵣₐ₃ to pᵣₐ₄ range (pᵣₐ₃>pᵣₐ₄) may be set such that a difference value between any period value within the pᵣₐ₃ to pᵣₐ₄ range and the period p_{IDT} of the IDT electrode 100 is 5% or less of the period p_{IDT}.

For example, it is possible to set and apply the pᵣₐ₃ to pᵣₐ₄ range, which is the period range of the second reflection part, such that the difference value between pᵣₐ₃ and p_{IDT} corresponds to 4% of p_{IDT} and pᵣₐ₄ has the same period value as p_{IDT}.

As described above, by setting all period values within the period range (pᵣₐ₁ to pᵣₐ₂) of the first reflection part 410 to be shorter than p_{IDT} and setting all period values within the period range (pᵣₐ₃ to pᵣₐ₄) of the second reflection part 420 to be longer than p_{IDT}, while setting each period range such that the overall phase change of the acoustic wave becomes substantially the same as that of the IDT electrode 100, it is possible to cancel the spurious response while minimizing the change in the resonance frequency of the acoustic wave device.

Conversely, if the difference value between the period of the reflection electrodes of the phase dispersion reflector and the period of the IDT electrode exceeds 5% of the period of the IDT electrode, a new resonance point may be formed beyond phase dispersion and parasitic resonance may occur. Therefore, the 5% period variation range of the phase dispersion reflector as described above can be considered a critical numerical value.

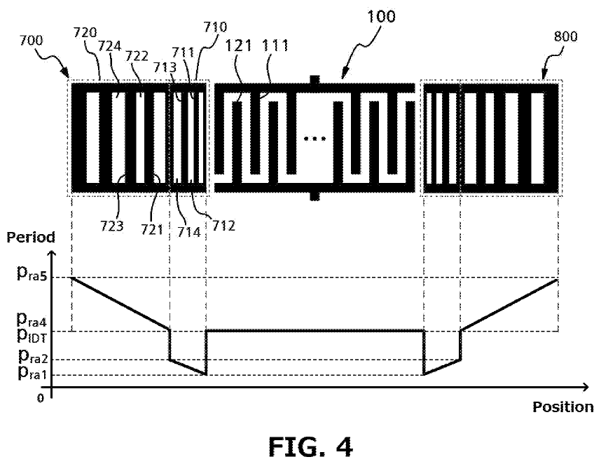

Meanwhile, an acoustic wave device according to still another embodiment of the present invention will be described with reference to FIG. 4. FIG. 4 shows a configuration of an acoustic wave device according to still another embodiment of the present invention and details regarding a change in period of an IDT electrode and a phase dispersion reflector accordingly.

In the embodiment shown in FIG. 4, the IDT electrode 100 is the same as the embodiment shown in FIG. 2 described above, and there is a difference in the configuration of the phase dispersion reflector. Hereinafter, redundant descriptions of the same configuration will be avoided, and descriptions will focus on portions that differ between the embodiments.

The acoustic wave device according to the embodiment shown in FIG. 3 described above was configured such that the period of the first reflection part of the phase dispersion reflector gradually increases in the acoustic wave propagation direction in a period range shorter than the period of the IDT electrode, and the period of the second reflection part gradually decreases in the acoustic wave propagation direction in a period range longer than the period of the IDT electrode.

Also, in the embodiment shown in FIG. 4, a phase dispersion reflector 700 is divided into a first reflection part 710 and a second reflection part 720, and has a configuration in which a period length varies depending on a position. Since a phase dispersion reflector 800 provided at the opposite end of the IDT electrode 100 also has the same configuration, the phase dispersion reflector 700 will be described below, but a description of the opposite phase dispersion reflector 800 will be omitted.

The first reflection part 710 of the phase dispersion reflector 700 provided adjacent to the end portion of the IDT electrode 100 is set to have a period shorter than p_{IDT}, which is the period of the IDT electrode 100, such that the period of the plurality of reflection electrodes (711, 713, etc.) gradually increases in a direction away from the IDT electrode 100 in the propagation direction of the acoustic wave from a position adjacent to the IDT electrode 100. The second reflection part 720 is set to have a period longer than p_{IDT}, which is the period of the IDT electrode 100, such that the period of the plurality of reflection electrodes (721, 723, etc.) gradually increases in the direction away from the IDT electrode 100 in the propagation direction of the acoustic wave from a position connected to the first reflection part 710.

As the period of the plurality of reflection electrodes (711, 713, etc.) of the first reflection part 710 gradually increases, an interval (712, 714, etc.) between the reflection electrodes also gradually increases. As the period of the plurality of reflection electrodes (721, 723, etc.) of the second reflection part 720 gradually increases, an interval (722, 724, etc.) between the reflection electrodes also gradually increases.

As shown in FIG. 4, the period of the reflection electrodes (711, 713, etc.) of the first reflection part 710 of the phase dispersion reflector 700 changes such that the period gradually increases from pᵣₐ₁ to pᵣₐ₂ in the acoustic wave propagation direction from a position adjacent to the IDT electrode. The period of the reflection electrodes (721, 723, etc.) of the second reflection part 720 of the phase dispersion reflector 700 changes such that the period gradually increases from pᵣₐ₄ to pᵣₐ₅ in the acoustic wave propagation direction.

At this point, the period pᵣₐ₁ to pᵣₐ₂ of the first reflection part 710 is set at a period length shorter than p_{IDT} of the IDT electrode 100, and the period pᵣₐ₄ to pᵣₐ₅ of the second reflection part 720 is set at a period length equal to or longer than p_{IDT} of the IDT electrode 100. As shown in FIG. 4, pᵣₐ₁<pᵣₐ₂<p_{IDT}≤pᵣₐ₄<pᵣₐ₅.

At the position of the period pᵣₐ₁ of the first reflection part 710, the period length of the reflection electrode is formed to be the shortest, and gradually increases toward the position pᵣₐ₂. Accordingly, the speed of phase change of the acoustic wave passing through the first reflection part 710 also changes rapidly and then changes slowly little by little, so that the phase of the acoustic wave is dispersed multi-directionally. As the period length gradually increases toward the position pᵣₐ₅ from the position of the period pᵣₐ₄ of the second reflection part 720, the speed of phase change of the acoustic wave becomes increasingly slower, maintaining the overall phase change of the acoustic wave similarly to the phase change of the acoustic wave in the IDT electrode. Thus, the change in the resonance frequency characteristic can be minimized while suppressing the occurrence of the spurious response.

The period pᵣₐ₁ to pᵣₐ₂ of the first reflection part 710 of the phase dispersion reflector 700 is in a range shorter than the electrode period p_{IDT} of the IDT electrode 100, and the pᵣₐ₁ to pᵣₐ₂ range (pᵣₐ₁<pᵣₐ₂) may be set such that a difference value between any period value within the pᵣₐ₁ to pᵣₐ₂ range and the period p_{IDT} of the IDT electrode 100 is 5% or less of the period p_{IDT}. For example, it is possible to set and apply the pᵣₐ₁ to pᵣₐ₂ range, which is the period range of the first reflection part, such that the difference value between p_{IDT} and pᵣₐ₁ corresponds to 3% of p_{IDT} and the difference value between p_{IDT} and pᵣₐ₂ corresponds to 2% of p_{IDT}.

The period pᵣₐ₄ to pᵣₐ₅ of the second reflection part 720 of the phase dispersion reflector 700 is in a range longer than the electrode period p_{IDT} of the IDT electrode 100, and the pᵣₐ₄ to pᵣₐ₅ range (pᵣₐ₄<pᵣₐ₅) may be set such that a difference value between any period value within the pᵣₐ₄ to pᵣₐ₅ range and the period p_{IDT} of the IDT electrode 100 is 5% or less of the period p_{IDT}. For example, it is possible to set and apply the pᵣₐ₄ to pᵣₐ₅ range, which is the period range of the second reflection part, such that pᵣₐ₄ has the same period value as p_{IDT} and the difference value between pᵣₐ₅ and p_{IDT} corresponds to 4% of p_{IDT}.

As described above, by setting all period values within the period range (pᵣₐ₁ to pᵣₐ₂) of the first reflection part 710 to be shorter than p_{IDT} and setting all period values within the period range (pᵣₐ₄ to pᵣₐ₅) of the second reflection part 720 to be longer than p_{IDT}, while setting each period range such that the overall phase change of the acoustic wave becomes substantially the same as that of the IDT electrode 100, it is possible to cancel the spurious response while minimizing the change in the resonance frequency of the acoustic wave device.

Conversely, if the difference value between the period of the reflection electrodes of the phase dispersion reflector and the period of the IDT electrode exceeds 5% of the period of the IDT electrode, a new resonance point may be formed beyond phase dispersion and parasitic resonance may occur. Therefore, the 5% period variation range of the phase dispersion reflector as described above can be considered a critical numerical value.

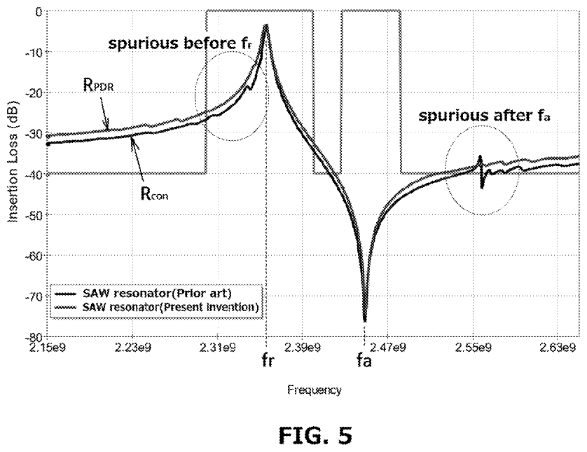

Meanwhile, as an acoustic wave device according to an embodiment of the present invention, a frequency response of a SAW resonator to which the phase dispersion reflector as shown in FIG. 2 described above is applied, and a frequency response of a typical SAW resonator are shown in FIG. 5.

In the graph of insertion loss versus frequency shown in FIG. 5, R_{con} represents a response of a typical SAW resonator (in a case where the period lengths of the IDT and the reflector are constant as shown in FIG. 1), and R_{PDR} represents a response of a SAW resonator having the phase dispersion reflector as shown in FIG. 2.

As shown in FIG. 5, looking at the frequency response curve (R_{con}) of the typical SAW resonator, it can be seen that a spurious response occurred before a resonance frequency (fᵣ) and a spurious response occurred after an anti-resonance frequency (fₐ) . And looking at the frequency response curve (R_{PDR}) of the SAW resonator equipped with the phase dispersion reflector according to the present invention, it can be seen that both the spurious response before the resonance frequency (fᵣ) and the spurious response after the anti-resonance frequency (fₐ) have decreased, while the positions and characteristics of the resonance frequency (fᵣ) and the anti-resonance frequency (fₐ) are maintained the same.

As described above, by dispersing the phase of the reflected acoustic wave using the phase dispersion reflector of the acoustic wave device according to the present invention, the spurious response can be significantly reduced. Likewise, by appropriately adjusting the change in phase using the reflection part having a long period length along with the phase dispersion of the acoustic wave to approximate the phase change according to the period of the IDT electrode, the characteristics of the resonance frequency and the anti-resonance frequency can be maintained as they are.

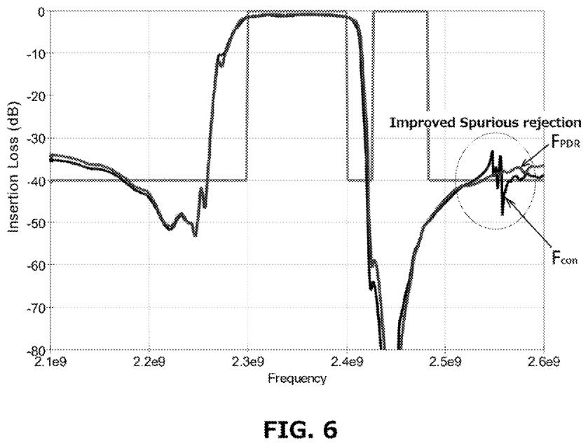

By using the acoustic wave device according to the present invention capable of reducing the spurious response as described above, it is possible to suppress the occurrence of ripples in a passband on the frequency response of a filter and improve a rejection characteristic in an out-of-band region, which is illustrated in FIGS. 6 to 8. FIGS. 6 to 8 are graphs showing a comparison of frequency responses between a filter composed of a typical SAW resonator and a filter composed of the acoustic wave device according to the present invention.

In FIGS. 6 to 8, F_{con} represents a response of a filter composed of a typical SAW resonator (in a case where the period lengths of the IDT and the reflector are constant as shown in FIG. 1), and F_{PDR} represents a response of a filter composed of the SAW resonator having the phase dispersion reflector according to the present invention.

FIG. 6 shows that spurious responses are generated in out-of-band rejection of the frequency response (F_{con}) of a conventional filter composed of a typical SAW resonator. Looking at the frequency response (F_{PDR}) of the filter composed of the acoustic wave device according to the present invention, it can be seen that the spurious response is significantly reduced in the out-of-band region, thereby improving the rejection characteristic.

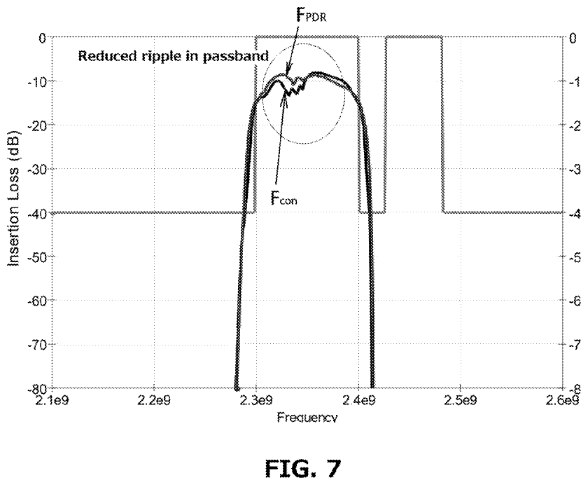

In FIG. 7, it can be seen that a ripple due to spurious responses is generated in a passband of the frequency response (F_{con}) of a conventional filter composed of a typical SAW resonator. However, looking at the frequency response (F_{PDR}) of the filter composed of the acoustic wave device according to the present invention in FIG. 7, it can be seen that the ripple is significantly reduced in the passband.

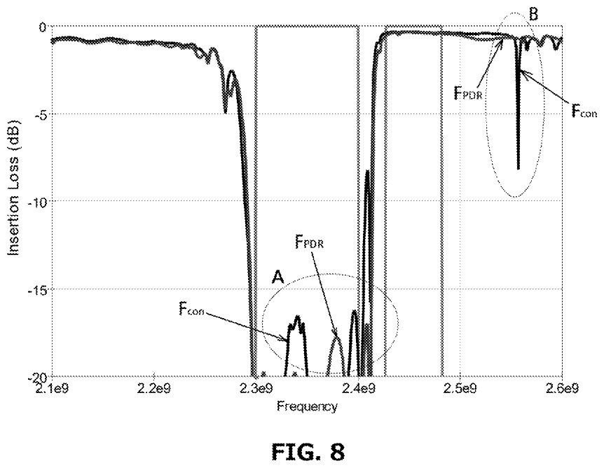

Referring to FIG. 8, it can be seen that a significant ripple occurred in the passband (refer to portion A shown in FIG. 8) and a spurious response occurred in the out-of-band region (refer to portion B shown in FIG. 8) in the frequency response (F_{con}) of a conventional filter composed of a typical SAW resonator.

And, as shown in FIG. 8, looking at the frequency response (F_{PDR}) of the filter composed of the acoustic wave device according to the present invention, it can be seen that the ripple is significantly reduced in the passband (refer to portion A shown in FIG. 8), and the spurious response is also significantly reduced in the out-of-band region (refer to portion B shown in FIG. 8).

It can be seen that such suppression of ripple generation in the passband and improvement of the rejection characteristic in the out-of-band region is a result of reducing the spurious response due to the acoustic wave phase dispersion of the acoustic wave device according to the present invention.

What is claimed is:

1. An acoustic wave device having an acoustic wave phase dispersion structure, comprising:
a piezoelectric substrate;
an IDT electrode disposed on the piezoelectric substrate and including a plurality of electrode fingers configured to convert an electrical signal into an acoustic wave on the piezoelectric substrate; and
a phase dispersion reflector disposed in a propagation direction of the acoustic wave generated by the IDT electrode, respectively, and including a plurality of reflection electrodes configured to reflect the acoustic wave to the IDT electrode,
wherein a period of the plurality of reflection electrodes is set such that a phase of the reflected acoustic wave is dispersed.

2. The acoustic wave device of claim 1, wherein the phase dispersion reflector is configured such that a portion of the plurality of reflection electrodes disposed adjacent to the IDT electrode is set to have at least one period shorter than a period of the IDT electrode, and the remainder of the plurality of reflection electrodes is set to have at least one period longer than the period of the IDT electrode.

3. The acoustic wave device of claim 1, wherein the phase dispersion reflector comprises:
a first reflection part including a plurality of reflection electrodes having a period set to induce phase dispersion of the acoustic wave generated from the IDT electrode; and
a second reflection part including a plurality of reflection electrodes having a period set to change a phase of the acoustic wave passing through the first reflection part to satisfy an acoustic wave reflection condition to the IDT electrode.

4. The acoustic wave device of claim 1, wherein the phase dispersion reflector comprises:
a first reflection part including a plurality of reflection electrodes set to have at least one period shorter than a period of the IDT electrode; and
a second reflection part including a plurality of reflection electrodes set to have at least one period longer than the period of the IDT electrode.

5. The acoustic wave device of claim 1, wherein the phase dispersion reflector comprises:
a first reflection part configured to have a period shorter than a period of the IDT electrode, wherein the period of the plurality of reflection electrodes is set to gradually increase in a direction away from the IDT electrode from a position adjacent to the IDT electrode; and
a second reflection part configured to have a period longer than the period of the IDT electrode, wherein the period of the plurality of reflection electrodes is set to gradually increase or gradually decrease in a direction away from the IDT electrode from a position connected to the first reflection part.

6. The acoustic wave device of claim 3, wherein the phase dispersion reflector is configured by setting the number of reflection electrodes included in the second reflection part to be at least four times greater than the number of reflection electrodes included in the first reflection part.

7. The acoustic wave device of claim 4, wherein the phase dispersion reflector is configured by setting the number of reflection electrodes included in the second reflection part to be at least four times greater than the number of reflection electrodes included in the first reflection part.

8. The acoustic wave device of claim 5, wherein the phase dispersion reflector is configured by setting the number of reflection electrodes included in the second reflection part to be at least four times greater than the number of reflection electrodes included in the first reflection part.

9. The acoustic wave device of claim 3, wherein the phase dispersion reflector is configured such that:
each of one or more periods set for the plurality of reflection electrodes included in the first reflection part is shorter than a period of the IDT electrode, and a difference value from the period of the IDT electrode is set to be 5% or less of the period of the IDT electrode; and
each of one or more periods set for the plurality of reflection electrodes included in the second reflection part is longer than the period of the IDT electrode, and a difference value from the period of the IDT electrode is set to be 5% or less of the period of the IDT electrode.

10. The acoustic wave device of claim 4, wherein the phase dispersion reflector is configured such that:
each of one or more periods set for the plurality of reflection electrodes included in the first reflection part is shorter than a period of the IDT electrode, and a difference value from the period of the IDT electrode is set to be 5% or less of the period of the IDT electrode; and
each of one or more periods set for the plurality of reflection electrodes included in the second reflection part is longer than the period of the IDT electrode, and a difference value from the period of the IDT electrode is set to be 5% or less of the period of the IDT electrode.

11. The acoustic wave device of claim 5, wherein the phase dispersion reflector is configured such that:
each of one or more periods set for the plurality of reflection electrodes included in the first reflection part is shorter than a period of the IDT electrode, and a difference value from the period of the IDT electrode is set to be 5% or less of the period of the IDT electrode; and
each of one or more periods set for the plurality of reflection electrodes included in the second reflection part is longer than the period of the IDT electrode, and a difference value from the period of the IDT electrode is set to be 5% or less of the period of the IDT electrode.

12. The acoustic wave device of claim 3, wherein a period of the phase dispersion reflector is set such that an average value of periods set for all reflection electrodes of the phase dispersion reflector is equal to a period of the IDT electrode or included in a preset difference value range.

13. The acoustic wave device of claim 4, wherein a period of the phase dispersion reflector is set such that an average value of periods set for all reflection electrodes of the phase dispersion reflector is equal to a period of the IDT electrode or included in a preset difference value range.

14. The acoustic wave device of claim 5, wherein a period of the phase dispersion reflector is set such that an average value of periods set for all reflection electrodes of the phase dispersion reflector is equal to a period of the IDT electrode or included in a preset difference value range.
